(19) United States
(12) Patent Application Publication
(10) Pub. No.: US 2006/0093003 A1
(43) Pub. Date: May 4, 2006

(54) Semiconductor laser device and process for preparing the same

(75) Inventors: Ki Won Moon, Suwon (KR); Jong Ik Park, Seoul (KR); Yu Seung Kim, Anyang (KR); Hye Ran Oh, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/151,552

(22) Filed: Jun. 14, 2005

(30) Foreign Application Priority Data
Oct. 29, 2004 (KR) 10-2004-87198

(51) Int. Cl. H01S 5/00

(52) U.S. Cl. 372/46.01; 372/45.01

(57) ABSTRACT

Provided are a high output semiconductor laser device that is capable of inhibiting changes in far-field horizontal (FFH) due to increased output thereof, and a process for preparing the same. The semiconductor laser device in accordance with the present invention comprises a first clad layer of a first conductivity type formed on a substrate; an active layer formed on the first clad layer; and a second clad layer of a second conductivity type formed on the active layer and including an upper region having a ridge structure, wherein the second clad layer has at least one high refractivity layer inserted into the ridge structure, the high refractivity layer having a higher refractive index than the second clad layer.

### RELATED APPLICATION

The present application is based on, and claims priority from, Korean Application Number 2004-87198, filed Oct. 29, 2004, the disclosure of which is incorporated by reference herein in its entirety.

### BACKGROUND OF THE INVENTION

1. Field of the Invention

The present invention relates to a semiconductor laser device, and more particularly to a high output semiconductor laser device that is capable of reducing changes in far-field horizontal (FFH) due to increased output thereof, and a process for preparing the same.

2. Description of the Related Art

Recently, owing to popularization of CD-RWs and DVD-RWs, there has been greatly increased demand for high output semiconductor laser devices used as light sources. Generally, the semiconductor laser devices include p- and n-type type clad layers for injecting electric current, and an active layer, in which induced emission of photons substantially occurs, disposed between clad layers. Such semiconductor laser devices can acquire improved current injection efficiency by forming an upper clad layer (for example, a p-type clad layer) in the form of a ridge structure.

Furthermore, in the case of high output semiconductor laser devices utilized in DVD-Writers and the like, increased output thereof leads to changes in far-field horizontal (FFH). Therefore, when semiconductor laser devices are mounted for use in light pick-up devices for DVD-RW drives, changes in FFH due to high output may result in unstable write properties.

FIG. 1 is a cross-sectional view of a conventional high output semiconductor laser device. Referring to FIG. 1, the semiconductor laser device has a structure including an n-type AlGaInP clad layer 12, an undoped or doped active layer 13, a p-type lower AlGaInP clad layer 14, an etching stop layer 15, a p-type upper AlGaInP clad layer 16, a p-type GaInP cap layer 17 and a p-type GaAs contact layer 18, sequentially laminated on a GaAs substrate 11. The active layer 13 is made up of one or more quantum well layers and guiding layers. The etching stop layer 15 may be of a single composition thin film or of a multilayer structure having multiple layers.

In addition, the p-type upper AlGaInP clad layer 16 is made of a ridge structure in order to improve current injection efficiency, and a current blocking layer 21 for blocking current dispersion is formed around the clad layer 16. The p-type upper AlGaInP clad layer 16, a p-type GaInP cap layer 17 and a p-type GaAs contact layer 18 form a protrusion-shaped ridge part. Electrode structures for current injection (not shown) are formed on the upper surface of p-type GaAs contact layer 18 and the back surface of the substrate.

In the conventional semiconductor laser device having such a structure, current density and temperature in the active layer 13 region (a region A represented by a dotted line in FIG. 1) located below the ridge part become higher than the surrounding region as output increases. As a result, the refractivity (refractive index) became locally higher only in the region A, and thus FFH increases. If the FFH changes in response to increased output, the problem leading to unstable write properties is posed when the semiconductor laser device is practically mounted to use on the light pick-up system for DVD-RW drives.

Generally, it is possible to control FFH by adjusting the bottom width of the ridge part, a structure of the active region and the like, designing the larger FFH reduces the amount of changes in FFH due to increase of output.

FIG. 2 is a graph showing changes in FFH due to increased output of a conventional semiconductor laser device. Graph in FIG. 2 shows test results using the above-mentioned conventional semiconductor laser device. This graph was obtained by plotting differences between FFH at low output operation and high output operation, respectively, according to designed FFH value, assuming that at high output operation, refractivity of the quantum well layer in the active layer region (region A) below the ridge part increases by 2%. As shown in FIG. 2, if FFH is designed to be a large value, it is possible to reduce FFH increment due to increase of output (or increase of refractivity of the quantum well layer in the active layer within region A).

However, there is a limit to the increase of the FFH design value depending on conditions and environments in which the semiconductor laser device is used. Further, since FFH increment due to increased output diminishes only with movement along the line in FIG. 2, it is difficult to decrease FFH increment due to increased output with respect to the same FFH, by changing the bottom width of the ridge part or a structure of the active region.

Consequently, it is difficult to fundamentally improve changes in FFH due to increased output using only the conventional semiconductor laser devices. Thereby, when the semiconductor laser devices are practically mounted to use on the light pick-up device for DVD-RW drives, changes in FFH resulting from high output leads to unstable write properties.

### SUMMARY OF THE INVENTION

Therefore, the present invention has been made in view of the above problems, and it is an object of the present invention to provide a high output semiconductor laser device that is capable of inhibiting changes in far-field horizontal (FFH) due to increased output thereof.

It is another object of the present invention to provide a process for preparing a high output semiconductor laser device that is capable of inhibiting changes in far-field horizontal (FFH) due to increased output thereof.

In order to achieve the above object, a semiconductor laser device of the present invention comprises a first clad layer of a first conductivity type formed on a substrate; an active layer formed on the first clad layer; and a second clad layer of a second conductivity type formed on the active layer and including an upper region having a ridge structure, wherein the second clad layer has at least one high refractivity layer inserted into the ridge structure, the high refractivity layer having a higher refractive index than the second clad layer.

In one embodiment of the present invention, the first conductivity type is n-type, and the second conductivity type is p-type.

Preferably, the high refractivity layer has a refractive index of 3.30 to 3.62. More preferably, the high refractivity layer has a refractive index of 3.40 to 3.62. The refractive index of the high refractivity layer may be controlled by adjusting the Al composition ratio thereof.

The above-mentioned semiconductor laser device may further comprise an etching stop layer disposed below the ridge structure. In this case, the second clad layer includes a lower second clad layer formed under the etching stop layer and an upper second clad layer having a ridge structure formed on the etching stop layer. In addition, the semiconductor laser device may further include a cap layer of the second conductivity type formed on the second clad layer, and a contact layer of the second conductivity type formed on the cap layer.

In one embodiment of the present invention, the semiconductor laser device may be made of AlGaInP based (AlₓGa_{y}In_{(1-x-y)}P(0≦x≦1, 0≦y≦1, 0≦x+y≦1)) semiconductor. Alternatively, the semiconductor laser device may also be made of AlGaAs based semiconductor. In this case, the high refractivity layer may have a higher refractive index than the second clad layer by forming it in an Al composition ratio lower than that of the second clad layer.

In order to achieve another object of the present invention, a process is provided for preparing a semiconductor laser device, comprising:

sequentially forming a first clad layer of a first conductivity type, an active layer, a lower second clad layer of a second conductivity type, an etching stop layer, a high refractivity layer having a higher refractive index than the lower second clad layer, and an upper second clad layer of the second conductivity type having a lower refractive index than the high refractivity layer, on a substrate;

selectively etching the upper second clad layer and high refractivity layer to form a ridge structure including the upper second clad layer and high refractivity layer; and

forming a current blocking layer on the side of the ridge structure.

The process may further comprise forming a cap layer of the second conductivity type on the upper second clad layer, and forming a contact layer of the second conductivity type on the cap layer. Further, in the step of forming the ridge structure, the etching stop layer part on both sides of the ridge structure may be removed by selective etching.

The present invention provides a scheme for stabilizing write properties of DVD-RWs and the like using a semiconductor laser device by inhibiting changes in FFH value due to increased output of the semiconductor laser device. For this purpose, the semiconductor laser device in accordance with the present invention includes a high refractivity layer within the ridge structure of the second clad layer, the high refractivity layer having a higher refractive index than the second clad layer. By utilizing such a high refractivity layer, the semiconductor laser device in accordance with the present invention fundamentally improves changes in FFH values due to increased output.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional semiconductor laser device;

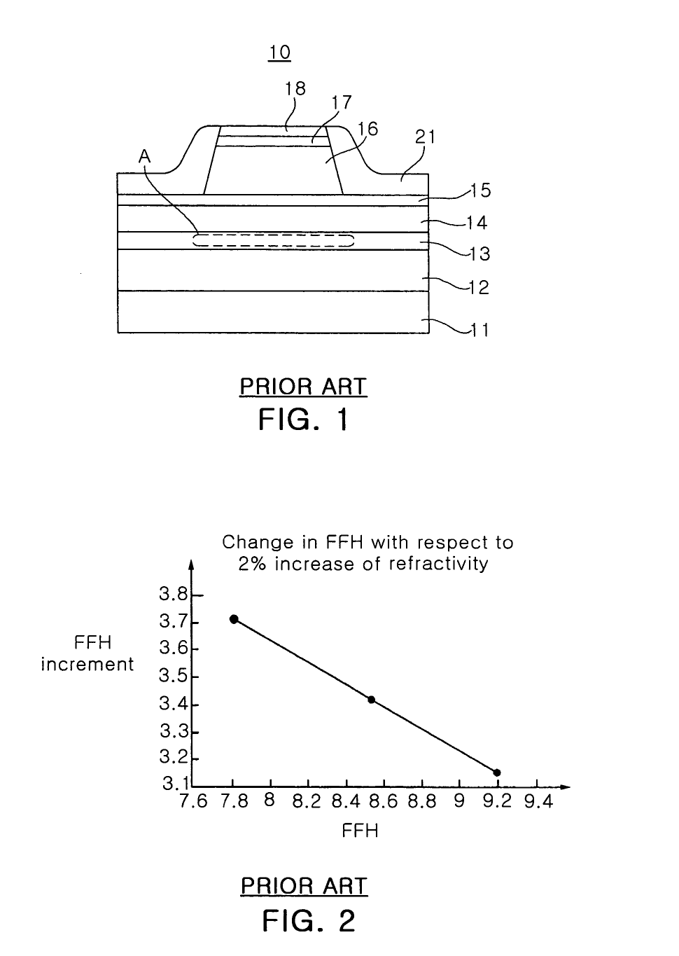

FIG. 2 is a graph showing FFH increment due to increased output of a conventional semiconductor laser device;

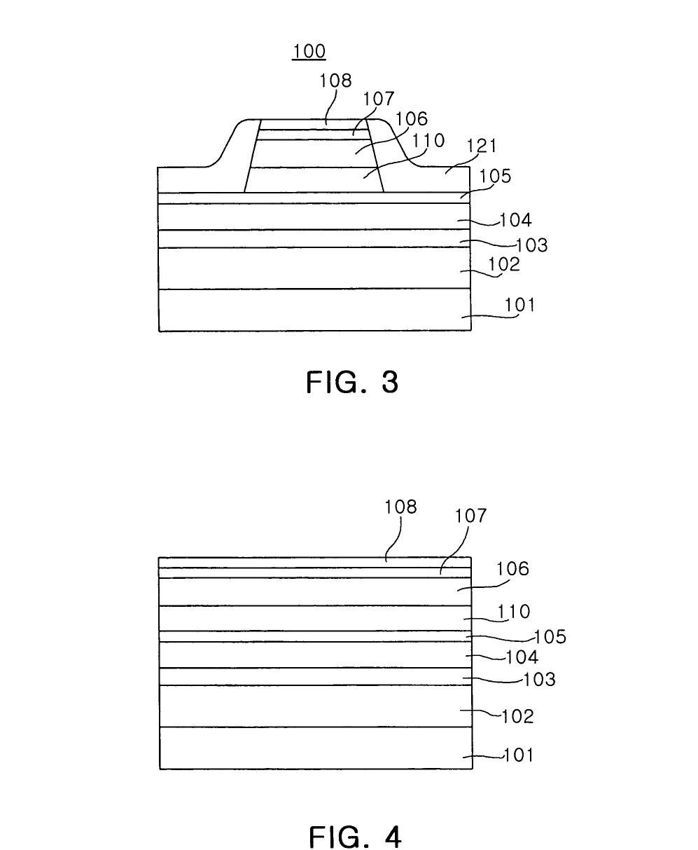

FIG. 3 is a cross-sectional view of a semiconductor laser device in accordance with one embodiment of the present invention;

FIGS. 4 through 9 are cross-sectional views and top views illustrating a process for preparing a semiconductor laser device in accordance with one embodiment of the present invention;

FIG. 10 is a graph showing refractivity and light intensity distribution with respect to a thickness direction of a conventional semiconductor laser device;

FIG. 11 is a graph showing refractivity and light intensity distribution with respect to a thickness direction of a semiconductor laser device in accordance with one embodiment of the present invention; and

FIG. 12 is a graph showing FFH increment due to increased output of a semiconductor laser device in accordance with one embodiment of the present invention.

### DESCRIPTION OF THE PREFERRED EMBODIMENTS

The present invention now will be described more fully with reference to the accompanying drawings, in which embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art. Therefore, in the drawings, shape and size of some elements may be exaggerated for clarity, and like numbers refer to like elements throughout.

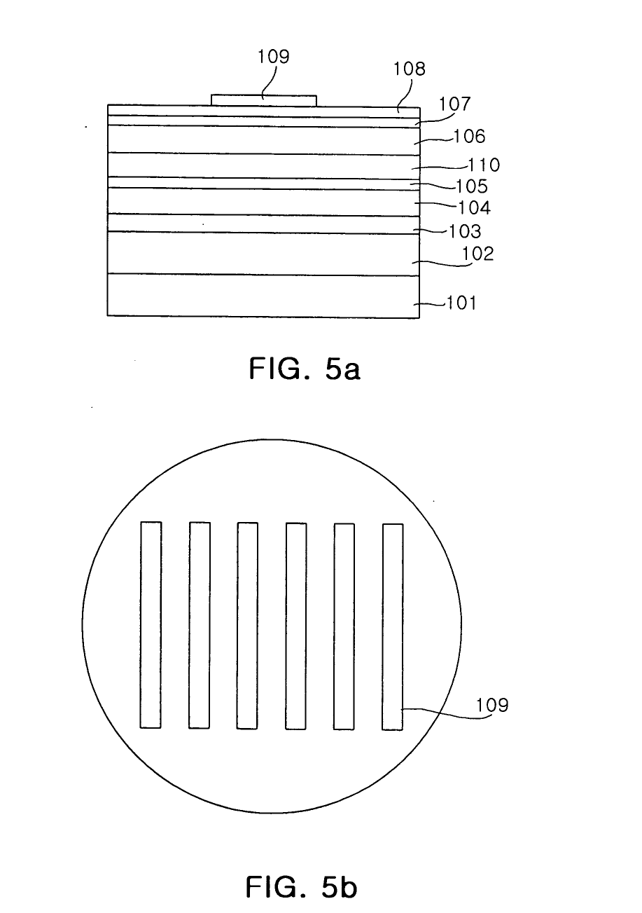

FIG. 3 shows a cross-sectional view of a semiconductor laser device in accordance with one embodiment of the present invention. The semiconductor laser device 100 shown in FIG. 3 schematically shows a cross-sectional structure of an AlGaInP based semiconductor laser device for a 650 nm oscillation wavelength. However, the present invention, for example, may be applied to an AlGaAs based semiconductor laser device configured to oscillate a laser of 780 nm wavelength.

Referring to FIG. 3, for example, an n-type clad layer 102 made of AlGaInP, an active layer 103, a p-type lower clad layer 104 made of AlGaInP and an etching stop layer 105 were sequentially laminated on a GaAs substrate 101. On the etching stop layer 105, a high refractivity layer 110, a p-type upper clad layer 106, a p-type cap layer 107 and a p-type contact layer 108 were sequentially laminated to form an upwardly protruded ridge part. In addition, around the ridge part including the p-type upper clad layer 106 was formed a current blocking layer 121. Electrode structures (not shown) for current injection were formed on the upper surface of the p-type contact layer 108 and the back surface of the substrate 101. The clad layers 102, 104 and 106, etching stop layer 105 and p-type cap layer 107 formed on the substrate may be formed of multilayer structures having different composition ratios or single-layer structures. In addition, FIG. 3 shows the etching stop layer 105 remaining on both sides of the ridge part, but it is possible to allow the etching stop layer 105 to be left below the ridge part while only removing it on both sides of the ridge part, depending on a desired embodiment.

The active layer 103 in the semiconductor laser device 100 is preferably formed of a multi quantum well structure composed of one or more quantum well layers and guiding layers. For example, the active layer 103 may be formed of a multilayer structure having AlGaInP layers and GaInP layers alternatively laminated thereon.

The p-type cap layer 107 serves to alleviate discontinuity of energy bands and for example, may be formed of a p-type GaInP layer containing no Al. Preferably, the p-type cap layer 107 has a thickness of less than 0.5 μm. In addition, the p-type contact layer 108 is designed for easy ohmic contact with the electrode formed on the upper part thereof and may be formed of a p-type GaAs layer, for example. The current blocking layer 121 serves to block current dispersion, and may be formed of an insulative dielectric material or n-type GaAs layer.

The high refractivity layer 110 may be formed of the AlGaIn layer and is inserted between the etching stop layer 105 and p-type upper clad layer 106 and then generally increases the refractivity of the ridge part. That is, by setting the Al composition ratio of the high refractivity layer 110 below that of the p-type clad layers 104 and 106, the refractive index of the high refractivity layer 110 become greater than that of the p-type clad layers 104 and 106. The present embodiment shows the ridge part having one high refractivity layer 110 inserted therein, but a plurality of high refractivity layers may be included in the ridge part, depending on a desired embodiment.

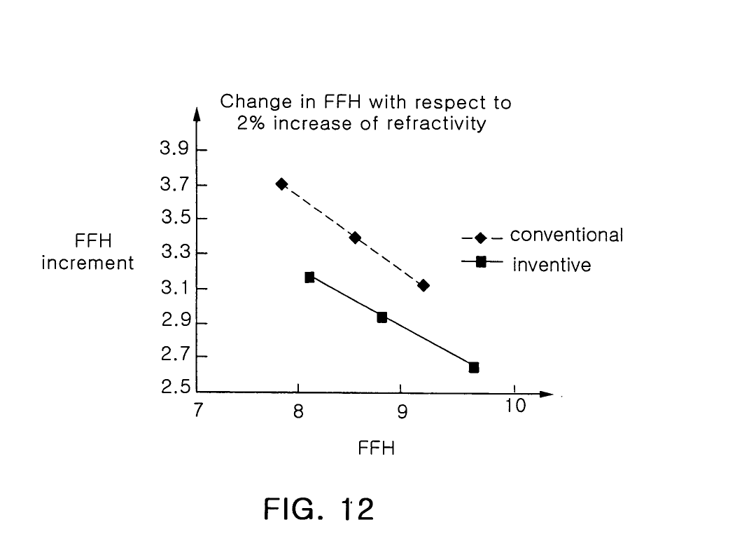

The present inventors have confirmed through repeated experimentation that addition of the high refractivity layer 110 to the ridge structure, as described above, may generally reduce changes in FFH due to increased output. It is understood that this is because when the high refractivity layer 110 is inserted between the p-type clad layers 104 and 106 and then included in the ridge part, the high refractivity layer 110 increases the refractive index of the ridge part to an extent that inhibits changes in FFH due to increased output, and thus serves to concentrate laser light to the central direction of the ridge part. Improved effects of changes in FFH due to insertion of the high refractivity layer 110 can be easily seen from the graph in FIG. 12, for example.

FIG. 12 is a graph exemplifying changes in FFH increment due to increased output of a semiconductor laser device in accordance with one embodiment of the present invention. Referring to FIG. 12, this embodiment also shows, similar to conventional devices, that increasing FFH leads to reduction of FFH increment due to increased output (increased output corresponding to 2% increase of refractivity). However, the present invention (represented by a solid line) shows that the FFH increment due to increased output is generally low, as compared to the conventional device (represented by a dotted) having no high refractivity layer. That is, for the same FFH value as set, FFH increment due to 2% increase of refractivity became significantly low compared to the conventional arts. Therefore, it is possible to inhibit changes in FFH due to high output without greatly increasing FFH set value, thus significantly stabilizing write properties of DVD-RW and the like.

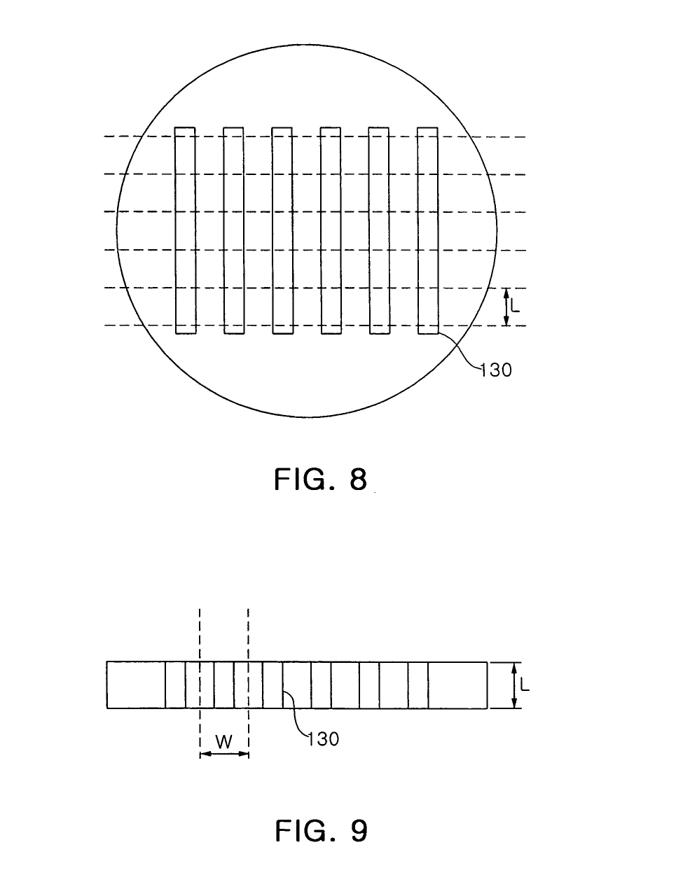

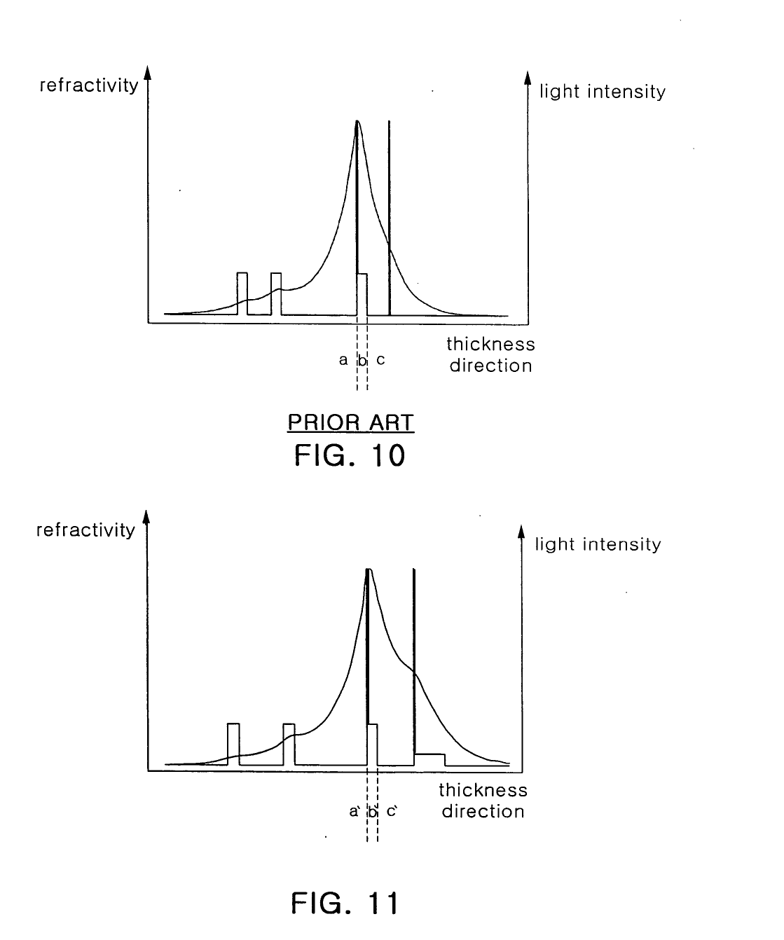

Further, as will be described in detail hereinafter, insertion of the high refractivity layer lowers optical density of the quantum well layer region in the active layer resulting in effects of inhibiting catastrophic optical damage (COD). As can be seen from FIG. 11, light intensity of the p-type clad layer region (c′) was relatively highly distributed in the present invention, compared to the conventional art (see region c in FIG. 10). As a result, light intensity is less distributed in the quantum well region of the active layer 103 as compared to the conventional art, and COD phenomenon due to excessive optical density in the active layer is inhibited.

Now, a process for preparing a semiconductor laser device in accordance with one embodiment of the present invention will be described. In the process in accordance with this embodiment, unlike a conventional method, after performing an additional process of forming a high refractivity layer on an etching stop layer, a p-type upper clad layer having a lower refractive index than the high refractivity layer was formed.

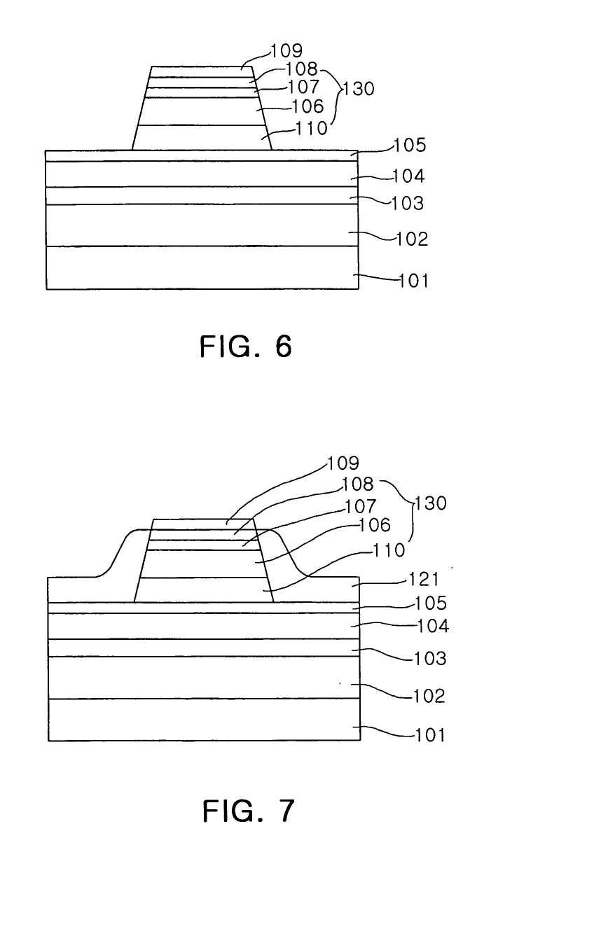

FIGS. 4 through 9 are cross-sectional views and top views illustrating a process for preparing a semiconductor laser device in accordance with one embodiment of the present invention.

First, referring to FIG. 4, for example, an n-type clad layer 102 of AlGaInP, an active layer 103 having a multi quantum well structure of AlGaInP/GaInP, a p-type lower clad layer 104 of AlGaInP, an etching stop layer 105, a high refractivity layer 110, a p-type upper clad layer 106 of AlGaInP, a p-type cap layer 107 and a p-type contact layer 108 were sequentially formed on a GaAs substrate 101.

Next, referring to FIG. 5a, a mask film of silicone oxide (SiO₂) or silicone nitride (SiN) was formed on the p-type contact layer 108, and then selectively etched through a photolithography process to form a mask film pattern (109) for forming a ridge part. FIG. 5b is a top view illustrating the mask film pattern 109 of FIG. 5a on a wafer. As shown in FIG. 5b, the mask film pattern 109 is present in the form of a plurality of stripes on the wafer.

Thereafter, as shown in FIG. 6, as the etching mask, the mask film pattern 109 was subjected to dry etching and/or wet etching to form a ridge structure. As a result, a high refractivity layer 110, a p-type upper clad layer 106, a p-type cap layer 107 and a p-type contact layer 108 form a ridge part 130 for improving current injection. In this embodiment, when etching to form the ridge structure, portions of the etching stop layer 105 on both sides of the ridge part remained, but those portions 105 may also be removed when etching to form the ridge structure.

Next, referring to FIG. 7, around the ridge part was formed a current blocking layer 121 for blocking current dispersion. The current blocking layer 121 may be formed by using Metal Organic CVD (MOCVD), Molecular Beam Epitaxy (MBE), Plasma Enhanced CVD (PECVD) and sputtering, for example, and may be made of insulative materials such as dielectric or semiconductor materials having conductivity opposite that of the ridge part (for example, n-type GaAs). Then, after removing the mask film pattern 109, electrode structures (not shown) were formed on the upper surface of the p-type contact layer 108 and back surface of the substrate 101, respectively. The electrode structures may be formed of metal materials such as Ti, Pt, Au and Ni or p-type conductive semiconductor materials or a multilayer structure of metal and semiconductor material.

Next, as represented by a dotted line on the top view of FIG. 8, a line was drawn on the wafer by methods such as scribing and cleaving, followed by cutting and division of the wafer into a plurality of bar forms. Reference symbol “L” in FIG. 8 represents a length of the semiconductor laser device (or a length of resonance cavity).

Next, a dielectric thin film was coated on the cross-section of the bar by methods such as sputtering or PECVD, and the bars were cut and divided into the respective semiconductor laser devices having a predetermined width (W) and length (L) by methods such as etching or cleaving, as represented by a dotted line on the top view of FIG. 9. Then, each upper and lower electrode of the respective semiconductor devices was connected for current injection. The semiconductor laser devices in accordance with this embodiment obtained through such a preparation process inhibited changes in FFH due to increased output by controlling the refractive index of the high refractivity layer 110, as described above, thus maintaining a constant FFH value, and alleviating optical density of the quantum well layer in the active layer 103.

In the above embodiment of the present invention, even though the process for preparing AlGaInP based semiconductor laser devices was illustrated using a GaInP/AlGaInP layer as the active layer, the present invention is applicable to the process for preparing AlGaAs based semiconductor laser devices using GaAs/AlGaAs as the active layer. Similarly, in the case of preparing AlGaAs based semiconductor laser devices, changes in FFH due to high output may be inhibited by forming the high refractivity layer 110 having an Al composition ratio smaller than that of the p-type clad layer (i.e., having a greater refractive index than that of the p-type clad layer) in the ridge structure.

In addition, in the above-mentioned process, a selective etching process for forming the ridge structure was performed following lamination of the p-type contact layer 108 on the p-type cap layer 107, but the p-type contact layer 108 may be laminated on the p-type cap layer 107 after performing the selective etching process for forming the ridge structure.

### EXAMPLE

In order to further illustrate improved properties of a semiconductor laser device in accordance with the present invention, a comparison experiment was performed on change properties in FFH between the semiconductor laser device in accordance with one embodiment of the present invention and a conventional semiconductor laser device.

The semiconductor laser device used for this experiment was an AlGaInP based semiconductor laser device, and was prepared so as to satisfy conditions such as layer thickness, refractive index and Al composition ratio listed in Table 1 below. As described in Table 1 below, the semiconductor laser device in accordance with this Example includes the high refractivity layer between the etching stop layer and p-type upper clad layer.

TABLE 1

| | | Refractive | Al composition |
|---|---|---|---|
| Example | Thickness (μm) | Index | ratio (%) |
| p-type upper clad | 1.2 | 3.3454 | 70 |
| layer (p-AlGaInP) | | | |
| High refractivity | 0.2 | 3.3617 | 65 |
| layer (p-AlGaInP) | | | |
| Etching stop layer | 0.003 | 3.6218 | 0 |
| (p-AlGaInP/GaInP) | 0.004 | 3.3617 | 65 |
| | 0.003 | 3.6218 | 0 |
| | 0.004 | 3.3617 | 65 |
| | 0.003 | 3.6218 | 0 |
| p-type lower clad | 0.1 | 3.3454 | 70 |
| layer (p-AlGaInP) | 0.15 | 3.3454 | 70 |
| Active | 0.04 | 3.4026 | 53 |
| layer (AlGaInP/GaInP) | 0.0063 | 3.6218 | 0 |
| | 0.004 | 3.4026 | 53 |
| | 0.0063 | 3.6218 | 0 |
| | 0.004 | 3.4026 | 53 |
| | 0.0063 | 3.6218 | 0 |
| | 0.005 | 3.4026 | 53 |
| n-type clad layer (n- | 0.5 | 3.3454 | 70 |
| AlGaInP) | 0.08 | 3.4026 | 53 |
| | 0.3 | 3.3454 | 70 |
| | 0.08 | 3.4026 | 53 |
| | 3 | 3.3454 | 70 |

As described in Table 1, the clad layer, etching stop layer and active layer were of a multilayer structure, respectively, and the direction from the bottom to top of Table 1 corresponds to the real direction from the lower layers to upper layers of the semiconductor laser device. In addition, the Al composition ratio listed in Table 1 was expressed as percentage and represents of the ratio of moles of Al to moles of Al and Ga contained in AlGaInP.

Since Al Ga and In are Group III elements, except for P (Group V), about 1M P is present in 1M AlGaInP. In addition, about 0.24 to 0.26M In is present in 1M AlGaInP, in AlGaInP layer which is generally utilized in the current semiconductor laser device. Therefore, the sum of Al and Ga moles present in 1M AlGaInP is about 0.25 moles. The Al composition ratio listed in Table 1 may be understood as the ratio of moles of Al to 0.25 moles, the sum of Al and Ga moles. As shown in Table 1, the high refractivity layer of this Example has a greater refractive index (3.3617) than the p-type clad layer (3.3454) by forming the high refractivity layer so as to have the Al composition ratio (65%) smaller than that of the p-type clad layer (70%).

Meanwhile, as a Comparative Example for comparison with the above-mentioned Example, the conventional semiconductor device was prepared under conditions listed in Table 2 below. Meaning for upper and lower positions and Al composition ratios of the respective layers included in the conventional semiconductor device of the Comparative Example were the same as the above-mentioned Example described with reference to Table 1, provided that in the Comparative Example, the high refractivity layer was not inserted into the ridge part, but the p-type upper clad layer of AlGaInP was directly formed on the etching stop layer. The thicknesses of the respective layers in the Comparative Example were almost the same as the above-mentioned Example, and the p-type upper clad layer of the Comparative Example was formed to the thickness corresponding to the sum of the p-type upper clad layer thickness and high refractivity layer thickness in the above-mentioned Example.

TABLE 2

| Comparative | | Refractive | Al composition |
|---|---|---|---|
| Example | Thickness (μm) | Index | ratio (%) |
| p-type upper | 1.4 | 3.3454 | 70 |
| clad layer | | | |
| (p-AlGaInP) | | | |
| Etching stop | 0.003 | 3.6218 | 0 |
| layer (p- | 0.004 | 3.3454 | 70 |
| AlGaInP/GaInP) | 0.003 | 3.6218 | 0 |
| | 0.004 | 3.3454 | 70 |
| | 0.003 | 3.6218 | 0 |
| p-type lower | 0.2 | 3.3454 | 70 |
| clad layer (p- | | | |
| AlGaInP) | | | |
| Active layer | 0.05 | 3.4026 | 53 |
| (AlGaInP/GaInP) | 0.0063 | 3.6218 | 0 |
| | 0.004 | 3.4026 | 53 |
| | 0.0063 | 3.6218 | 0 |
| | 0.004 | 3.4026 | 53 |
| | 0.0063 | 3.6218 | 0 |
| | 0.005 | 3.4026 | 53 |
| n-type clad | 0.6 | 3.3454 | 70 |
| layer (n- | 0.08 | 3.4026 | 53 |
| AlGaInP) | 0.2 | 3.3454 | 70 |
| | 0.08 | 3.4026 | 53 |
| | 3 | 3.3454 | 70 |

FIGS. 10 and 11 show measurement results of refractive index (refractivity) and light intensity distribution for the semiconductor laser devices of the above-mentioned Comparative Example and Example. Referring to graphs of FIGS. 10 and 11, refractive index and light intensity distribution were shown based on thickness direction of the semiconductor laser devices as the horizontal axis. The direction from left to right of the horizontal axis in graphs corresponds to the direction from the lower layers to upper layers of the semiconductor laser devices. More specifically, the protruded refractivity distribution parts b and b′, positioned at points where light intensity was at a maximum peak in graphs of FIGS. 10 and 11, correspond to the respective active layers, and starting from such points, left sides a and a′ correspond to the respective n-type clad layers and right sides c and c′ correspond to the respective p-type clad layers.

Referring to FIG. 11, protruded refractivity distribution of the high refractivity layer appears at a predetermined distance spaced apart from the refractivity distribution part b′ corresponding to the active layer in the positive direction of the horizontal axis. This means that the refractive index of the high refractivity layer is higher than the adjacent p-type clad layer. In the case of the above-mentioned Example having such a refractivity distribution, the light intensity on the p-type clad layer side c′ was relatively highly distributed as compared to the Comparative Example of FIG. 10. Therefore, optical density of the active layer was relatively decreased and thereby a COD phenomenon due to excessive optical density in the active layer (in particular, a quantum well layer in the active layer) may be inhibited.

FFH increments due to increased output of semiconductor laser devices of the Example and Comparative Example were measured. The results are shown in a graph of FIG. 12. Dotted line on the graph of FIG. 12 represents characteristics of FFH change in the Comparative Example, and the solid line represents characteristics of FFH change in the Example. As shown in FIG. 12, FFH increment due to increased output corresponding to 2% increase of refractivity in the Example was generally low, as compared to the Comparative Example. This means that characteristics of FFH change at a high output operation are improved by the high refractivity layer of the Example.

As described above, in accordance with the present invention, insertion of the high refractivity layer having a greater refractive index than the p-type clad layer into the ridge part may inhibit changes in FFH due to increased output of semiconductor laser devices. Therefore, when semiconductor laser devices are mounted for use in light pick-up devices for DVD-RW drives, write properties at high output operation can be stabilized. In addition, insertion of the high refractivity layer into the ridge part may reduce optical density in a quantum well layer region of an active layer, thus inhibiting development of a COD phenomenon.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor laser device, comprising:
a first clad layer of a first conductivity type formed on a substrate;
an active layer formed on the first clad layer; and
a second clad layer of a second conductivity type formed on the active layer and including an upper region having a ridge structure,
wherein the second clad layer has at least one high refractivity layer inserted into the ridge structure, the high refractivity layer having a higher refractive index than the second clad layer.

2. The semiconductor laser device as set forth in claim 1, wherein the high refractivity layer has a refractive index of 3.30 to 3.62.

3. The semiconductor laser device as set forth in claim 1, wherein the high refractivity layer has a refractive index of 3.40 to 3.62.

4. The semiconductor laser device as set forth in claim 1, wherein the device further comprises an etching stop layer disposed below the ridge structure, and
the second clad layer includes a lower second clad layer formed under the etching stop layer and an upper second clad layer having a ridge structure formed on the etching stop layer.

5. The semiconductor laser device as set forth in claim 1, further comprising:
a cap layer of the second conductivity type formed on the second clad layer; and
a contact layer of the second conductivity type formed on the cap layer.

6. The semiconductor laser device as set forth in claim 1, wherein the semiconductor laser device is made of AlGaInP based semiconductor or AlGaAs based semiconductor, and the Al composition ratio of the high refractivity layer is lower than that of the second clad layer.

7. A process for preparing a semiconductor laser device, comprising:
sequentially forming a first clad layer of a first conductivity type, an active layer, a second lower clad layer of a second conductivity type, an etching stop layer, a high refractivity layer having a higher refractive index than the lower second clad layer, and an upper second clad layer of the second conductivity type having a lower refractive index than the high refractivity layer, on a substrate;
selectively etching the upper second clad layer and high refractivity layer to form a ridge structure including the upper second clad layer and high refractivity layer; and
forming a current blocking layer on the side of the ridge structure.

8. The process as set forth in claim 7, further comprising:
forming a cap layer of the second conductivity type on the upper second clad layer; and
forming a contact layer of the second conductivity type on the cap layer.

9. The process as set forth in claim 7, wherein in the step of forming the ridge structure, the etching stop layer part on both sides of the ridge structure is removed by selective etching.
